(19) United States
(12) Patent Application Publication
(10) Pub. No.: US 2026/0370235 A1
(43) Pub. Date: Nov. 19, 2026

(54) METHOD FOR CALCULATING SAMPLING TIME OFFSET, TIME-INTERLEAVED SAMPLING DEVICE, AND READABLE MEDIUM

(71) Applicant: SANECHIPS TECHNOLOGY CO., LTD., Shenzhen (CN)

(72) Inventors: Yang ZHOU, Shenzhen, Guangdong (CN); Jian WANG, Shenzhen, Guangdong (CN); Jiawen SU, Shenzhen, Guangdong (CN)

(21) Appl. No.: 19/478,042

(22) PCT Filed: Mar. 19, 2024
(86) PCT No.: PCT/CN2024/082441

§ 371 Date: Oct. 23, 2025

(30) Foreign Application Priority Data
Apr. 25, 2023 (CN) 202310471770.3

(51) Int. Cl. H03M 1/12; H03M 1/10

(52) U.S. Cl. CPC H03M 1/1245; H03M 1/1023

(57) ABSTRACT

Provided is method for calculating a sampling time offset, including: acquiring sampling results of each sub-sampling module on input signal; determining sampling time offset of reference sub-sampling module based on the sampling results of the reference sub-sampling module, first and second theoretical results corresponding to each sampling result, with the first theoretical result being theoretical value of the input signal at predetermined sampling time corresponding to each sampling result, the second theoretical result being theoretical value of derivative signal at predetermined sampling time corresponding to each sampling result, and the derivative signal being derivative of the input signal; and determining sampling time offsets of non-reference sub-sampling modules based on the sampling time offset of the reference sub-sampling module, the sampling results of each non-reference sub-sampling module, first and second theoretical results corresponding to each sampling result. The present disclosure further provides time-interleaved sampling device and computer readable medium.

### CROSS REFERENCE TO RELATED APPLICATIONS

The present disclosure claims the priority to Chinese Patent Application No. 202310471770.3 filed with the CNIPA on Apr. 25, 2023, the contents of which are incorporated herein by reference in their entirety.

### TECHNICAL FIELD

The present disclosure relates to, but is not limited to, the field of Time Interleaved (TI) sampling technology.

### BACKGROUND

A TI Analog-to-Digital Converter (ADC) includes a plurality of sub-ADCs, each sub-ADC performs sampling at a different predetermined sampling time, and sampling results of the sub-ADCs are combined to obtain a total sampling result, so that a total sampling rate of the total sampling result is multiple times sampling rates of the sub-ADCs. Due to actual precision limitation of a product, a certain offset (i.e., sampling time offset, also called a sampling time skew) may exist between an actual sampling time and the predetermined sampling time of each sub-ADC, and the different sub-ADCs have different sampling time offsets, resulting in deterioration of quality of the final total sampling result. Therefore, the sampling time offset of each sub-ADC needs to be determined and calibrated, so as to eliminate the influence of the sampling time offset.

However, existing methods for calculating the sampling time offset are complex in operation, difficult in convergence, and long in time.

### SUMMARY

The present disclosure provides a method for calculating a sampling time offset, a time-interleaved sampling device, and a computer readable medium.

In a first aspect, an embodiment of the present disclosure provides a method for calculating a sampling time offset applied to a time-interleaved sampling device including a plurality of sub-sampling modules, the time-interleaved sampling device being configured to receive an input signal, and each sub-sampling module being configured to sample the input signal at a respective predetermined sampling time; and the method including: acquiring a plurality of sampling results obtained by each sub-sampling module by sampling the input signal at a plurality of predetermined sampling times; determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling modules than the reference sub-sampling module.

In a second aspect, an embodiment of the present disclosure provides a time-interleaved sampling device, including a processor, a storage device, and a plurality of sub-sampling modules; the time-interleaved sampling device being configured to receive an input signal, and each sub-sampling module being configured to perform sampling at a respective predetermined sampling time; the storage device storing a computer program executable by the processor, and the computer program, when executed by the processor, causing the processor to perform the following operations: acquiring a plurality of sampling results of each sub-sampling module on the input signal, with each sampling result being a result obtained by performing sampling at one predetermined sampling time by the sub-sampling module: determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling module than the reference sub-sampling module.

In a third aspect, an embodiment of the present disclosure provides a computer readable medium having stored thereon a computer program which, when executed by a processor, causes the processor to implement the method for calculating a sampling time offset according to any embodiment of the present disclosure.

### BRIEF DESCRIPTION OF DRAWINGS

In the drawings for the embodiments of the present disclosure:

FIG. 1 is a flowchart illustrating a method for calculating a sampling time offset according to an embodiment of the present disclosure;

FIG. 2 is another flowchart illustrating a method for calculating a sampling time offset according to an embodiment of the present disclosure;

FIG. 3 is a schematic diagram illustrating a process of calibrating sampling time offsets for a TI ADC according to an embodiment of the present invention;

FIG. 4 is a block diagram of a time-interleaved sampling device according to an embodiment of the present disclosure; and

FIG. 5 is a block diagram of a computer readable medium according to an embodiment of the present disclosure.

### DETAIL DESCRIPTION OF EMBODIMENTS

In order to enable those of ordinary skill in the art to better understand the technical solutions of the present disclosure, a method for calculating a sampling time offset, a time-interleaved sampling device, and a computer readable medium provided in the embodiments of the present disclosure are described in detail below with reference to the drawings.

The present disclosure will be described more fully below with reference to the drawings, but the embodiments illustrated may be embodied in different forms, and the present disclosure should not be interpreted as being limited to the embodiments described below. Rather, the embodiments are provided to make the present disclosure thorough and complete, and are intended to enable those of ordinary skill in the art to fully understand the scope of the present disclosure.

The drawings for the embodiments of the present disclosure are intended to provide a further understanding of the embodiments of the present disclosure and constitute a part of the specification. Together with the specific embodiments of the present disclosure, the drawings are used to explain the present disclosure, but do not constitute any limitation to the present disclosure. The above and other features and advantages will become more apparent to those of ordinary skill in the art from the description of the specific embodiments with reference to the drawings.

The present disclosure can be described with reference to plans and/or cross-sectional views with the aid of idealized schematic diagrams of the present disclosure. Accordingly, the exemplary drawings may be modified according to manufacturing techniques and/or tolerances.

All the embodiments of the present disclosure and the features therein may be combined with each other if no conflict is incurred.

The terms used herein are merely used to describe the specific embodiments, and are not intended to limit the present disclosure. The term “and/or” used herein includes any and all combinations of one or more associated listed items. The terms “one” and “the” used herein which indicate a singular form are intended to include a plural form, unless expressly stated in the context. The terms “include” and “be made of” used herein indicate the presence of the described features, integers, operations, elements and/or components, but do not exclude the presence or addition of one or more other features, integers, operations, elements, components and/or combinations thereof.

Unless otherwise defined, all terms (including technical and scientific terms) used herein have the same meaning as commonly understood by those of ordinary skill in the art. It should be further understood that terms, such as those defined in commonly used dictionaries, should be interpreted as having a meaning that is consistent with a meaning in the context of the related technology and the background of the present disclosure, and should not be interpreted in an idealized or overly formal sense unless expressly so defined herein.

The present disclosure is not limited to the embodiments illustrated by the drawings, but includes modifications to configuration formed based on a manufacturing process. Thus, regions shown in the drawings are illustrative, and shapes of the regions shown in the drawings illustrate specific shapes of regions of elements, but are not intended to make limitations.

In a wireless communication system, an ADC is configured to convert an analog signal into a digital signal, and sampling quality of the ADC has a great influence on performance of the communication system. In particular, due to high frequency and large bandwidth, signals in a fifth generation mobile communication (5G) system have relatively high requirements on the ADC; but due to hardware limitation, a sampling rate of the ADC cannot be increased with demand indefinitely.

In view of the above, the TI sampling technology may be adopted, a plurality of (e.g., M) sub-ADCs are disposed in a TI ADC, and each sub-ADC performs sampling respectively at a different predetermined sampling time in each sampling period, and sampling results (also referred to as “sampled quantized signals”) from the sub-ADCs are combined into a total sampling result. Thus, a total sampling rate of the total sampling result is, for example, M times sampling rates of the sub-ADCs, which greatly reduces requirements on layout design and manufacturing process of each ADC.

However, due to unavoidable errors in properties of a multiphase clock generation circuit and a transmission delay in the TI ADC, a certain offset (i.e., a sampling time offset, also called a sampling time skew) may exist between an actual sampling time and the predetermined sampling time of each sub-ADC; moreover, since the sub-ADCs operate independent of each other, the different sub-ADCs have different sampling time offsets. Therefore, if the total sampling result is synthesized directly based on the sampling results of the sub-ADCs, a large number of sampling points in the total sampling result are the sampling results not actually sampled at the desired time, such that quality of the total sampling result deteriorates, and a large number of spurs exist in the total sampling result, which further reduces a Spurious-Free Dynamic Range (SFDR) of the TI ADC, increases quantization errors, elevates Noise Spectrum Density (NSD), and reduces signal-to-noise ratio.

Therefore, the sampling time offset of each sub-ADC needs to be determined in advance, and sampling-time-offset calibration needs to be performed accordingly, so as to eliminate the spurs caused by the sampling time offset, reduce the quantization errors, suppress the NSD, and increases the signal-to-noise ratio.

In some related technologies, the actual sampling time may be adaptively adjusted based on a correlation difference between adjacent channels (sub-ADCs), or a specific value of the sampling time offset may be further calculated in consideration of derivative information; however, this method needs cooperative iterative computation on data of the plurality of sub-ADCs, resulting in complex operation and relatively long convergence time.

In some other related technologies, one or more channels (sub-ADCs) may be set as one or more reference channels in hardware, and each sub-ADC may be aligned with the one or more reference channels for calibration; however, this method still needs cooperative computation using the data of the different sub-ADCs, also resulting in complex operation.

Thus, the methods for calculating the sampling time offset in the related technologies are complex in operation, difficult in convergence, and long in time.

In a first aspect, an embodiment of the present disclosure provides a method for calculating a sampling time offset, which is applied to a time-interleaved sampling device including a plurality of sub-sampling modules, the time-interleaved sampling device is configured to receive an input signal, and each sub-sampling module is configured to sample the input signal at a respective predetermined sampling time.

The time-interleaved sampling device includes the plurality of sub-sampling modules, so that after the time-interleaved sampling device receives the input signal, each sub-sampling module respectively samples the signal at a different predetermined sampling time, and obtains one sampling result at each predetermined sampling time, and sampling results of all the sub-sampling modules are combined, thereby obtaining a total sampling result with a high total sampling rate.

The predetermined sampling time of each sub-sampling module is “periodical”, that is, each sub-sampling module has a different predetermined sampling time in one period, and relative positions of the predetermined sampling time of each sub-sampling module in different periods are the same (e.g., 8 ns after each period begins).

The embodiment of the present disclosure is used for calculation of a sampling time offset of each sub-sampling module in the time-interleaved sampling device; after the sampling time offset is obtained, a calibration scheme can be further set based on the sampling time offset, so that the time-interleaved sampling device can calibrate a sampling process based on the calibration scheme in actual use (that is, while sampling an actual signal), thereby finally obtaining a sampling-time-offset-free total sampling result.

The time-interleaved sampling device may be in the form of a TI ADC, and each sub-sampling module may be a sub-ADC.

It should be understood that a specific form of the time-interleaved sampling device is not limited to the TI ADC. For example, the time-interleaved sampling device may directly process the acquired signal in an analog domain instead of performing analog-to-digital conversion on the acquired signal.

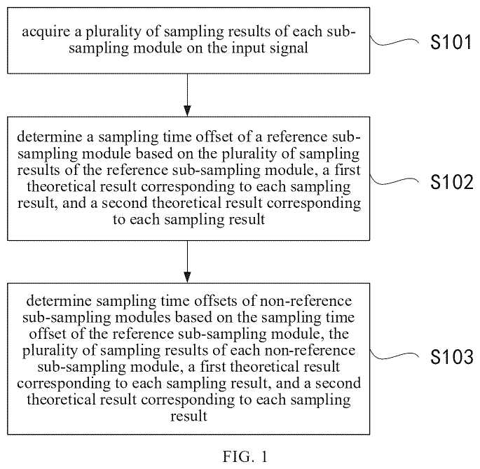

Referring to FIG. 1, a method of calculating a sampling time offset according to an embodiment of the present disclosure may include operations S101 to S103.

At operation S101, a plurality of sampling results of each sub-sampling module on the input signal are acquired.

Each sampling result is a result obtained by performing sampling at one predetermined sampling time by the sub-sampling module.

In the embodiment of the present disclosure, a specific “input signal (also called a test signal)” for a sampling time offset calculation process is generated first, and then is input to the time-interleaved sampling device; the input signal can last for a plurality of periods, so that each sub-sampling module samples the input signal at a respective predetermined sampling time in each period to obtain one sampling result (sampled quantized signal), and thus obtains a plurality of sampling results in the plurality of periods.

“Theoretically”, the sub-sampling module is desired to perform sampling at the predetermined sampling time, but due to the sampling time offset, the sampling result is actually obtained at a time in the presence of the sampling time offset.

At operation S102, a sampling time offset of a reference sub-sampling module is determined based on the plurality of sampling results of the reference sub-sampling module, a first theoretical result corresponding to each sampling result, and a second theoretical result corresponding to each sampling result.

The reference sub-sampling module is one of the plurality of sub-sampling modules; the first theoretical result is a theoretical value of the input signal at a predetermined sampling time corresponding to each sampling result; and the second theoretical result is a theoretical value of a derivative signal at a predetermined sampling time corresponding to each sampling result, and the derivative signal is a derivative of the input signal.

Each sampling result of the reference sub-sampling module is an actual result obtained by performing sampling at the predetermined sampling time (actually, the “theoretical” predetermined sampling time); the input signal has a “theoretical value” at the predetermined sampling time corresponding to each sampling result, and the “theoretical value” is called the first theoretical result corresponding to the sampling result; and the input signal is essentially a function, another function, i.e., the derivative signal, may be obtained by differentiating the input signal, the derivative signal also has a “theoretical value” at the predetermined sampling time corresponding to each sampling result, and the “theoretical value” is called the second theoretical result corresponding to the sampling result.

At the present operation, one sub-sampling module is selected as the reference sub-sampling module, and the sampling time offset (e.g., a time value in units of ps or ns) of the reference sub-sampling module is calculated based on the sampling results obtained by the reference sub-sampling module, the first theoretical result corresponding to each sampling result, and the second theoretical result corresponding to each sampling result.

At operation S103, sampling time offsets of non-reference sub-sampling modules are determined based on the sampling time offset of the reference sub-sampling module, the plurality of sampling results of each non-reference sub-sampling module, a first theoretical result corresponding to each sampling result, and a second theoretical result corresponding to each sampling result.

The non-reference sub-sampling modules are other sub-sampling modules than the reference sub-sampling module.

After the reference sub-sampling module is determined, all the other sub-sampling modules are determined as the non-reference sub-sampling modules.

For each non-reference sub-sampling module, the sampling time offset of the non-reference sub-sampling module is calculated based on the plurality of sampling results of the non-reference sub-sampling module, the first theoretical result corresponding to each sampling result, the second theoretical result corresponding to each sampling result, and the above calculated sampling time offset of the reference sub-sampling module.

That is, for the non-reference sub-sampling modules, the calculation of the sampling time offsets is based on the sampling time offset of the reference sub-sampling module in addition to the sampling results, the first theoretical results, and the second theoretical results of the non-reference sub-sampling modules.

In this way, the embodiment of the present disclosure achieves the calculation of the sampling time offsets of all the sub-sampling modules (including the reference sub-sampling module and the non-reference sub-sampling modules).

In the embodiment of the present disclosure, the sampling time offset of the reference sub-sampling module is directly calculated based on the sampling results of the reference sub-sampling module, and then the sampling time offset of each non-reference sub-sampling module is calculated based on the sampling time offset of the reference sub-sampling module and the sampling results of each non-reference sub-sampling module. As can be seen, the above processes of determining the sampling time offsets do not need cooperative computation on the data of the different sub-sampling modules (different channels) or iterative computation, so that the processes are simple in operation, short in time, and easy to implement, and are especially suitable for high-precision time-interleaved sampling device (such as a high-precision TI ADC).

In some embodiments, the input signal is a sinusoidal signal.

In an implementation of the embodiment of the present disclosure, the input signal input to the time-interleaved sampling device may be in the form of a sinusoidal signal, that is, a function of the input signal is:

sig(t)=Vpp*sin(2π*Fc*t);
where Vpp denotes a peak-to-peak value, and Fc denotes a carrier frequency.

Correspondingly, a derivative of the sine (sin) function is a cosine (cos) function, that is, a function of the derivative signal is:

cog(t)=Vpp*cos(2π*Fc*t).

As can be seen, at a time t, a value (theoretical value) of the input signal is Vpp*sin(2π*Fc*t), and a value (theoretical value) of the derivative signal is Vpp*cos(2π*Fc*t).

In some embodiments, the reference sub-sampling module is a sub-sampling module having the earliest predetermined sampling time.

In an implementation of the embodiment of the present disclosure, a sub-sampling module which performs sampling “first” in each period or a “first sub-sampling module” may be selected as the reference sub-sampling module, which simplifies the operation process.

It should be understood that it is also acceptable to take one of the other sub-sampling modules as the reference sub-sampling module.

In some embodiments, the input signal is a sinusoidal signal, and the reference sub-sampling module is the sub-sampling module having the earliest predetermined sampling time.

Determining the sampling time offset of the reference sub-sampling module based on the plurality of sampling results of the reference sub-sampling module, the first theoretical result corresponding to each sampling result, and the second theoretical result corresponding to each sampling result (S102) includes operation S1021.

At operation S1021, the sampling time offset

$${τ}_{1}^{est}$$

of the reference sub-sampling module is calculated by a formula

$${τ}_{1}^{est} = \frac{arctan ( \frac{{β}_{1}}{{α}_{1}} )}{2 π * F c}$$

where

$${α}_{1} = {\sum }_{n = 1}^{N} {sig\_s}_{1} ( n ) * {sin}_{1}^{e} ( n ) ;$$

$${β}_{1} = {\sum }_{n - 1}^{N} {sig\_s}_{1} ( n ) * {cos}_{1}^{e} ( n ) ;$$

$${sin}_{1}^{e} ( n ) = Vpp * sin ( 2 π * Fc * ( \frac{1 + M * ( n - 1 )}{Fs} ) ) ;$$

$${cos}_{1}^{e} ( n ) = Vpp * cos ( 2 π * Fc * ( \frac{1 + M * ( n - 1 )}{F s} ) ) ;$$

sig_s₁(n) denotes an n^{th} sampling result of the reference sub-sampling module,

$${sin}_{1}^{e} ( n )$$

denotes a first theoretical result corresponding to the n^{th} sampling result, and

$${cos}_{1}^{e} ( n )$$

denotes a second theoretical result corresponding to the n^{th} sampling result; and

Vpp denotes a peak-to-peak value of the input signal, Fc denotes a carrier frequency of the input signal, N denotes a total number of the sampling results, n denotes the n^{th} sampling result, M denotes the number of the sub-sampling modules, and Fs denotes a total sampling rate.

As can be seen, for example, when M sub-sampling modules are provided in total and each sub-sampling module performs sampling for N times, an n^{th} sampling result (an n^{th} sampling point, with n being a positive integer less than or equal to N) of a first sub-sampling module (the reference sub-sampling module) is actually obtained by the (1+M*(n−1))^{th} sampling in total, and accordingly, a predetermined sampling time for the n^{th} sampling point is equal to the number of times of sampling divided by the total sampling rate Fs of the time-interleaved sampling device, that is:

$$\frac{1 + M * ( n - 1 )}{Fs} .$$

As described above, the theoretical value of the input signal at the time t is Vpp*sin(2π*Fc*t), and the theoretical value of the derivative signal at the time t is Vpp*cos(2π*Fc*t), so that a first theoretical result and a second theoretical result which correspond to the n^{th} sampling result of the reference sub-sampling module are respectively:

$${sin}_{1}^{e} ( n ) = Vpp * sin ( 2 π * Fc * ( \frac{1 + M * ( n - 1 )}{Fs} ) ) ; and$$

$${cos}_{1}^{e} ( n ) = Vpp * cos ( 2 π * Fc * ( \frac{1 + M * ( n - 1 )}{Fs} ) ) .$$

Meanwhile, the n^{th} sampling result (sampled quantized signal) of the reference sub-sampling module is sig_s₁(n), i.e., a signal actually obtained by the reference sub-sampling module in the presence of an actual sampling time offset τ₁, and sig_s₁(n) is as follows:

$${sig\_s}_{1} ( n ) = Vpp * sin ( 2 π * Fc * ( \frac{1 + M * ( n - 1 )}{Fs} + {τ}_{1} ) ) .$$

Therefore, in a case where the sinusoidal signal is used as the input signal and the “first sub-sampling module” is taken as the reference sub-sampling module, the plurality of sampling results sig_s₁(n) of the reference sub-sampling module can be acquired first; and the first theoretical result

$${sin}_{1}^{e} ( n )$$

corresponding to each sampling result and the second theoretical result

$${cos}_{1}^{e} ( n )$$

corresponding to each sampling result can be calculated by the above formulas; then, based on the above contents, the two parameters α₁ and β₁ are respectively calculated by the above formulas; and finally, the sampling time offset

$${τ}_{1}^{e s t}$$

of the reference sub-sampling module (the first sub-sampling module) is calculated based on α₁ and β₁ by the above formula.

It should be understood that

$${τ}_{1}^{e s t}$$

denotes the sampling time offset of the reference sub-sampling module which is obtained by calculation, and τ₁ denotes the actual sampling time offset of the reference sub-sampling module.

Determining the sampling time offsets of the non-reference sub-sampling modules based on the sampling time offset of the reference sub-sampling module, the plurality of sampling results of each non-reference sub-sampling module, the first theoretical result corresponding to each sampling result, and the second theoretical result corresponding to each sampling result (S103) includes operation S1031.

At operation S1031, a sampling time offset

$${τ}_{m}^{est}$$

of a non-reference sub-sampling module having an m^{th} predetermined sampling time is calculated by a formula

$${τ}_{m}^{est} = \frac{arctan ( \frac{{β}_{m}}{{α}_{m}} )}{2 π * F c} ,$$

where

$${α}_{m} = {\sum }_{n = 1}^{N} {sig\_s}_{m} ( n ) * {sin}_{m}^{ε} ( n ) ;$$

$${β}_{m} = {\sum }_{n = 1}^{N} {sig\_s}_{m} ( n ) * {cos}_{m}^{e} ( n ) ;$$

$${sin}_{m}^{e} ( n ) = Vpp * sin ( 2 π \times Fc * ( \frac{m + M * ( n - 1 )}{F s} + {τ}_{1}^{est} ) ) ;$$

$${cos}_{m}^{e} ( n ) = Vpp * cos ( 2 π * Fc * ( \frac{m + M * ( n - 1 )}{Fs} + {τ}_{1}^{e s t} ) ) ;$$

and sig_sₘ(n) denotes an n^{th} sampling result of the non-reference sub-sampling module,

$${sin}_{m}^{e} ( n )$$

denotes a first theoretical result corresponding to the n^{th} sampling result, and

$${cos}_{m}^{e} ( n )$$

denotes a second theoretical result corresponding to the n^{th} sampling result.

As can be seen, except the reference sub-sampling module, for the sub-sampling module among the other sub-sampling modules (non-reference sub-sampling modules) which is the m^{th} (m is an integer greater than or equal to 2 and less than or equal to M) one to perform sampling, an n^{th} sampling result (an n^{th} sampling point, with n being a positive integer less than or equal to N) of the sub-sampling module is actually obtained by the (m+M*(n−1))^{th} sampling in total, and accordingly, a predetermined sampling time for the n^{th} sampling point is equal to the number of times of sampling divided by the total sampling rate Fs of the time-interleaved sampling device, that is:

$$\frac{m + M * ( n - 1 )}{Fs} .$$

Moreover, since the first sub-sampling module is taken as the reference sub-sampling module, that is, it is taken that all the other sub-sampling modules perform sampling under the condition of taking the first sub-sampling module as a “reference”, the sampling time offset of the reference sub-sampling module may affect all the following non-reference sub-sampling modules, that is, the sampling time offset of the reference sub-sampling module may exist in the sampling processes of the other non-reference sub-sampling modules as a “reference”; thus, the predetermined sampling time of the n^{th} sampling result of the m^{th} sub-sampling module (non-reference sub-sampling module) is:

$$\frac{m + M * ( n - 1 )}{Fs} + {τ}_{1}^{est} .$$

Further, a first theoretical result and a second theoretical result which correspond to the n^{th} sampling result of the m sub-sampling module (non-reference sub-sampling module) are respectively:

$${sin}_{m}^{e} ( n ) = V p p * sin ( 2 π \times F c * ( \frac{m + M * ( n - 1 )}{Fs} + {τ}_{1}^{est} ) ) ; and$$

$${cos}_{m}^{e} ( n ) = Vpp * cos ( 2 π * Fc * ( \frac{m + M * 〈 n - 1 )}{F s} + {τ}_{1}^{e s t} ) ) .$$

Accordingly, due to a sampling time offset τₘ of the m^{th} sub-sampling module, the n^{th} sampling result (sampled quantized signal) sig_sₘ(n) of the m^{th} sub-sampling module is actually as follows:

$${sig\_s}_{m} ( n ) = Vpp * sin ( 2 π * F c * ( \frac{m + M * ( n - 1 )}{F s} + {τ}_{1} + {τ}_{m} ) ) .$$

That is, it is taken that the non-reference sub-sampling module has the respective sampling time offset τₘ in addition to the sampling time offset τ₁ of the reference sub-sampling module (the first sub-sampling module).

Thus, after the sampling time offset

$${τ}_{1}^{e s t}$$

of the reference sub-sampling module (the first sub-sampling module) is acquired, the plurality of sampling results sig_sₘ(n) of each non-reference sub-sampling module can be acquired first; the first theoretical result

$${sin}_{m}^{e} ( n )$$

corresponding to each sampling result and the second theoretical result

$${cos}_{m}^{e} ( n )$$

corresponding to each sampling result can be calculated by the above formulas; then, based on the above contents, the two parameters αₘ and βₘ are respectively calculated by the above formulas; and finally, the sampling time offset

$${τ}_{m}^{e s t}$$

of the non-reference sub-sampling module is calculated based on αₘ and βₘ by the above formula.

As can be seen, the above formulas of

$${sin}_{m}^{e} ( n ) and {cos}_{m}^{e} ( n )$$

include

$${τ}_{1}^{est} .$$

Therefore, unlike the calculation process of the sampling time offset of the reference sub-sampling module, the sampling time offset of the reference sub-sampling module is desired to participate in the calculation processes of the sampling time offsets of the non-reference sub-sampling modules.

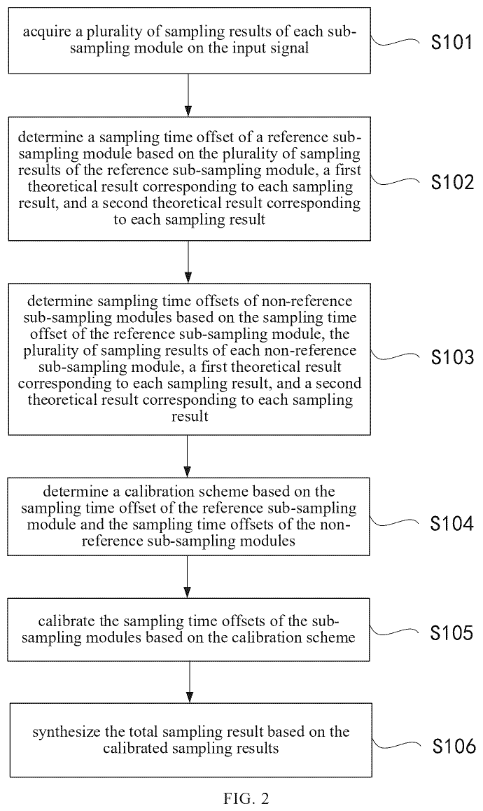

In some embodiments, referring to FIG. 2, after determining the sampling time offsets of the non-reference sub-sampling modules (S103), the method may further include operation S104.

At operation S104, a calibration scheme is determined based on the sampling time offset of the reference sub-sampling module and the sampling time offsets of the non-reference sub-sampling modules.

The calibration scheme is used for calibration of the sampling time offsets of the sub-sampling modules.

After the sampling time offsets of all the sub-sampling modules (including the reference sub-sampling module and the non-reference sub-sampling modules) are determined, a corresponding calibration scheme can be set based on the sampling time offsets, so that the time-interleaved sampling device can perform calibration based on the corresponding calibration scheme while subsequently performing a sampling process in normal use, thereby eliminating an influence of the sampling time offsets on the synthesized total sampling result.

In some embodiments, determining the calibration scheme based on the sampling time offset of the reference sub-sampling module and the sampling time offsets of the non-reference sub-sampling modules (S104) includes operation S1041.

At operation S1041, calibration factors are set for the sub-sampling modules based on the sampling time offsets of the sub-sampling modules.

The calibration factors are used for calibration of the sampling results of the sub-sampling modules.

In an implementation of the embodiment of the present disclosure, the sampling time offsets may be calibrated in a digital domain (e.g., a TI ADC), that is, the corresponding calibration factor is set for each sub-sampling module based on the respective sampling time offset, so that when the time-interleaved sampling device performs a sampling process in normal use, the time-interleaved sampling device may calibrate, based on the calibration factors, the sampling results (sampled quantized signals) directly obtained by the sub-sampling modules to obtain calibrated sampling results, and then synthesize the total sampling result based on the calibrated sampling results.

Alternatively, in some other embodiments, determining the calibration scheme based on the sampling time offset of the reference sub-sampling module and the sampling time offsets of the non-reference sub-sampling modules (S104) may include operation S1042.

At operation S1042, the predetermined sampling time of each sub-sampling module is adjusted based on the respective sampling time offset of the sub-sampling module.

In an implementation of the embodiment of the present disclosure, the calibration of the sampling time offsets may also be performed by other means.

Illustratively, the predetermined sampling time of a corresponding sub-sampling module may be changed based on the respective sampling time offset, so that based on the changed predetermined sampling time, the sub-sampling module is enabled to perform sampling actually at the original predetermined sampling time, thereby eliminating the sampling time offset.

For example, assuming that the sampling time offset of a certain sub-sampling module is −5 ps (that is, the sub-sampling module performs sampling 5 ps earlier than the original predetermined sampling time), the predetermined sampling time may be set to be 5 ps later, so that the sub-sampling module is enabled to perform sampling actually 5 ps earlier with the aim to perform sampling 5 ps later. Thus, the sub-sampling module finally performs sampling at the original predetermined sampling time.

It should be understood that the calibration of the sampling time offsets may be performed by other means. For example, the sampling time offsets may be calibrated in an analog domain (e.g., a TI ADC), which will not be described in detail herein.

In some embodiments, determining the calibration scheme based on the sampling time offset of the reference sub-sampling module and the sampling time offsets of the non-reference sub-sampling modules (S104) may include operation S1043.

At operation S1043, it is determined that the reference sub-sampling module is not calibrated; and a calibration scheme for the non-reference sub-sampling modules is determined based on the sampling time offset of the reference sub-sampling module and the sampling time offsets of the non-reference sub-sampling modules.

In an implementation of the embodiment of the present disclosure, since the sampling time offsets of the non-reference sub-sampling modules are actually calculated based on the sampling time offset of the reference sub-sampling module, in the calibration process, the sampling time offset of the reference sub-sampling module may “not” be calibrated, and the calibration of the sampling time offset of the reference sub-sampling module may be included in the calibration of the sampling time offsets of the non-reference sub-sampling modules.

For example, when the sampling time offset of the reference sub-sampling module is

$${τ}_{1}^{est} ,$$

it may be taken that the reference sub-sampling module does not have the sampling time offset, so that the reference sub-sampling module is not to be calibrated (for example, the sampling results of the reference sub-sampling module are directly used for the synthesis of the total sampling result); and for the non-reference sub-sampling modules having the sampling time offsets

$${τ}_{m}^{est} ,$$

it is taken that the sampling time offsets of the non-reference sub-sampling modules are

$${τ}_{1}^{est} + {τ}_{m}^{est} ,$$

and the non-reference sub-sampling modules are calibrated based on the sampling time offsets

$${τ}_{1}^{est} + {τ}_{m}^{e s t} .$$

Thus, referring to FIG. 2, after determining the calibration scheme (S104), the method may further include operations S105 and S106.

At operation S105, the sampling time offsets of the sub-sampling modules are calibrated based on the calibration scheme.

At operation S106, the total sampling result is synthesized based on the calibrated sampling results.

That is, after the calibration scheme is determined, when the time-interleaved sampling device performs a sampling process in normal use, the time-interleaved sampling device may perform calibration based on the corresponding calibration scheme, and perform synthesis of the total sampling result based on the sampling results having the sampling time offsets removed.

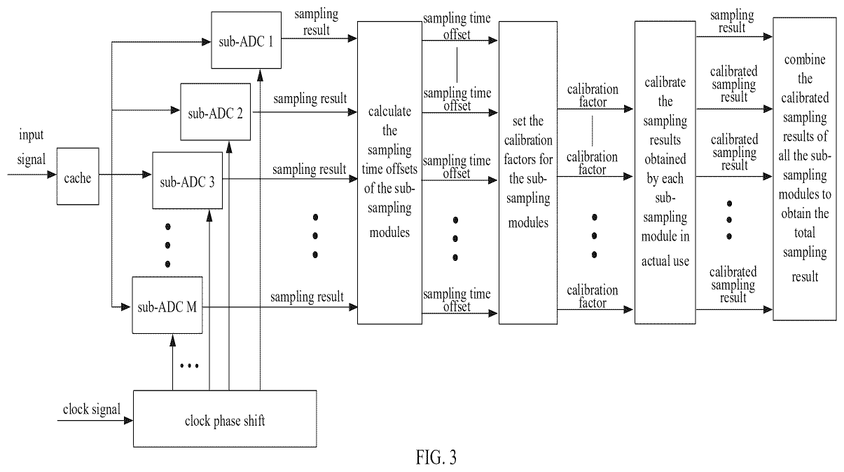

Illustratively, referring to FIG. 3, assuming that the time-interleaved sampling device is a TI ADC and each sub-sampling module is a sub-ADC, an input clock signal is subjected to clock phase shift and then sent to each sub-ADC as a trigger signal for performing sampling, and a clock phase shift amount for adjacent sub-ADCs is equal to a difference in the predetermined sampling time of the adjacent sub-ADCs, so that theoretically, each sub-ADC may respectively perform sampling at the respective predetermined sampling time. However, due to the errors in the properties of the clock generation circuit and the transmission delay, the sampling time offset may exist between the actual sampling time of each sub-ADC and the predetermined sampling time thereof.

Thus, if the input signal is the sinusoidal signal as described above, a first ADC is a reference sub-ADC, and the input signal is actually sampled after the sampling time offset of each sub-ADC is determined, then the corresponding processes of determining the calibration scheme, performing calibration, and synthesizing the total sampling result may include the following operations A104 to A106.

At operation A104, the corresponding calibration factors are set based on the sampling time offsets

$${τ}_{1}^{est} , {τ}_{2}^{e s t} , {τ}_{3}^{est} … {τ}_{M}^{e s t}$$

of the sub-ADCs.

A calibration factor is set for each non-reference sub-ADC based on the sampling time offsets of the sub-ADCs obtained by calculation.

For an m^{th} sub-ADC, the calibration factor is as follows:

$$cos ( 2 π * F c * {τ}_{m}^{e s t} ) ;$$

$$sin ( 2 π * F c * {τ}_{m}^{e s t} ) ,$$

where m is an integer greater than or equal to 2 and less than or equal to M, which indicates that no calibration factor is set for the first sub-ADC (the reference sub-ADC).

At operation A105, the sampling results obtained by each sub-ADC in actual use are calibrated.

As described above, an n^{th} sampling result (the sampled quantized signal) of the m^{th} sub-ADC is sig_sₘ(n), and a respective calibrated sampling result is sig_cₘ.

Thus, for the reference sub-ADC (the first sub-ADC), the calibrated sampling results are:

sig_c₁=sig_s₁(n).

That is, the reference sub-ADC is not calibrated, and the actual sampling results of the reference sub-ADC are directly used as the calibrated sampling results.

For an m^{th} sub-ADC (a non-reference sub-ADC) among other non-reference sub-ADCs, a calibrated n^{th} sampling result is:

$${sig\_c}_{m} ( n ) = {sig\_s}_{m} ( n ) * cos ( 2 π * F c * {τ}_{m}^{est} ) - {cos\_s}_{3 m} ( n ) * sin ( 2 π * F c * {τ}_{m}^{est} ) .$$

That is, the sampling results (the sampled quantized signals) directly obtained by the non-reference sub-ADCs are calibrated based on the calibration factors to obtain the calibrated sampling results.

At operation A106, the calibrated sampling results of all the sub-ADCs are combined to obtain the total sampling result sig_c.

That is, the total sampling result may be calculated by the following formula:

sig_c(n:M:end)=sig_cₘ(n).

It should be understood that in in the above formulas is a positive integer less than or equal to M, that is, the sampling results of the first sub-ADC (the reference sub-ADC) are not calibrated and are desired to be directly used for the synthesis of the total sampling result.

The simulation results show that in the cases where the number of the sub-sampling modules is 4, 8, 16, 32 or 64, a good calibration effect can be produced with the above calibration method at least when a maximum value of the sampling time offsets does not exceed 80 ps.

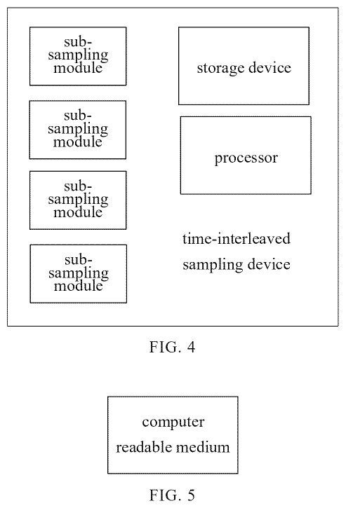

In a second aspect, referring to FIG. 4, an embodiment of the present disclosure provides a time-interleaved sampling device, including a processor, a storage device, and a plurality of sub-sampling modules; the time-interleaved sampling device is configured to receive an input signal, and each sub-sampling module is configured to perform sampling at a respective predetermined sampling time; the storage device stores a computer program executable by the processor, and the computer program, when executed by the processor, causes the processor to perform the following operations: acquiring a plurality of sampling results of each sub-sampling module on the input signal, with each sampling result being a result obtained by performing sampling at one predetermined sampling time by the sub-sampling module: determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling module than the reference sub-sampling module.

The time-interleaved sampling device provided in the embodiment of the present disclosure can perform the above method for calculating a sampling time offset, that is, the time-interleaved sampling device can calculate the sampling time offset of each sub-sampling module based on the input signal, and can further calibrate a sampling process in actual use based on the sampling time offsets.

In some embodiments, the time-interleaved sampling device is a TI ADC; and the sub-sampling modules are sub-ADCs.

In an implementation of the embodiment of the present disclosure, the time-interleaved sampling device provided in the embodiment of the present disclosure may be a TI ADC, and each sub-sampling module of the time-interleaved sampling device is a sub-ADC.

In some embodiments, the number of the sub-sampling modules is 2^{k}; and k is an integer greater than or equal to 2.

In an implementation of the embodiment of the present disclosure, the number of the sub-sampling modules (e.g., sub-ADCs) (i.e., the number of channels) in the time-interleaved sampling device provided in the embodiment of the present disclosure may be 4, 8, 16, 32, 64, or the like.

In a third aspect, referring to FIG. 5, an embodiment of the present disclosure provides a computer readable medium having stored thereon a computer program which, when executed by a processor, causes the processor to implement the method for calculating a sampling time offset according to any embodiment of the present disclosure.

The processor is a device having a data processing capability, and includes, but is not limited to, a Central Processing Unit (CPU); the storage device is a device having a data storage capability, and includes, but is not limited to, a Random Access Memory (RAM, more specifically, a Synchronous Dynamic RAM (SDRAM), a Double Data Rate SDRAM (DDR SDRAM), etc.), a Read-Only Memory (ROM), an Electrically Erasable Programmable Read-Only Memory (EEPROM), and a flash memory (FLASH); and an Input/Output (I/O) interface (read/write interface) is connected between the processor and the storage device, is capable of enabling information interaction between the processor and the storage device, and includes, but is not limited to, a data bus (Bus).

It should be understood by those of ordinary skill in the art that the functional modules/units in all or some of the operations, the systems, and the devices disclosed above may be implemented as software, firmware, hardware, or suitable combinations thereof.

If implemented as hardware, the division between the functional modules/units stated above does not necessarily correspond to the division of physical components; for example, one physical component may have a plurality of functions, or one function or operation may be performed through cooperation of several physical components.

Some or all of the physical components may be implemented as software executed by a processor, such as a CPU, a digital signal processor or a microprocessor, or may be implemented as hardware, or may be implemented as an integrated circuit, such as an application specific integrated circuit. Such software may be distributed on a computer-readable medium, which may include a computer storage medium (or a non-transitory medium) and a communication medium (or a transitory medium). As well known by those of ordinary skill in the art, the term “computer storage medium” includes volatile/nonvolatile and removable/non-removable media used in any method or technology for storing information (such as computer-readable instructions, data structures, program modules or other data). The computer storage medium includes, but is not limited to, an RAM (more specifically, an SDRAM, a DDR SDRAM, etc.), an ROM, an EEPROM, a FLASH or other magnetic disk storage, a Compact Disc Read Only Memory (CD-ROM), a Digital Versatile Disc (DVD) or other optical disk storage, a magnetic cassette, a magnetic tape, a magnetic disk or other magnetic storage devices, or any other medium which can be configured to store desired information and can be accessed by a computer. In addition, it is well known by those of ordinary skill in the art that the communication media generally include computer-readable instructions, data structures, program modules, or other data in modulated data signals such as carriers or other transmission mechanisms, and may include any information delivery medium.

The present disclosure discloses the exemplary embodiments using specific terms, but the terms are merely used and should be merely interpreted as having general illustrative meanings, rather than for the purpose of limitation. Unless expressly stated, it is apparent to those of ordinary skill in the art that the features, characteristics and/or elements described in connection with a particular embodiment can be used alone or in combination with the features, characteristics and/or elements described in connection with other embodiments. Therefore, it should be understood by those of ordinary skill in the art that various changes in forms and details can be made without departing from the scope of the present disclosure of the appended claims.

1. A method for calculating a sampling time offset applied to a time-interleaved sampling device comprising a plurality of sub-sampling modules, the time-interleaved sampling device being configured to receive an input signal, and each sub-sampling module being configured to sample the input signal at a respective predetermined sampling time; and the method comprising:
acquiring a plurality of sampling results of each sub-sampling module on the input signal, with each sampling result being a result obtained by performing sampling at one predetermined sampling time by each sub-sampling module;
determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and
determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling modules than the reference sub-sampling module.

2. The method of claim 1, wherein
the input signal is a sinusoidal signal.

3. The method of claim 1, wherein
the reference sub-sampling module is a sub-sampling module having an earliest predetermined sampling time.

4. The method of claim 1, wherein the input signal is a sinusoidal signal, and the reference sub-sampling module is a sub-sampling module having an earliest predetermined sampling time;
determining the sampling time offset of the reference sub-sampling module based on the plurality of sampling results of the reference sub-sampling module, the first theoretical result corresponding to each sampling result, and the second theoretical result corresponding to each sampling result comprises:
calculating the sampling time offset
$${τ}_{1}^{e s t}$$
of the reference sub-sampling module by a formula
$${τ}_{1}^{e s t} = \frac{arc tan ( \frac{{β}_{1}}{{α}_{1}} )}{2 π * F c} ,$$
where
$${α}_{1} = {\sum }_{n = 1}^{N} {sig\_s}_{1} ( n ) * {sin}_{1}^{e} ( n ) ;$$
$${β}_{1} = {\sum }_{n = 1}^{N} {sig\_s}_{1} ( n ) * {cos}_{1}^{e} ( n ) ;$$
$${sin}_{1}^{e} ( n ) = Vpp * sin ( 2 π * F c * ( \frac{1 + M * ( n - 1 )}{F s} ) ) ;$$
$${cos}_{1}^{e} ( n ) = Vpp * cos ( 2 π * F c * ( \frac{1 + M * ( n - 1 )}{F s} ) ) ;$$
sig_s₁(n) denotes an n^{th} sampling result of the reference sub-sampling module,
$${sin}_{1}^{e} ( n )$$
denotes a first theoretical result corresponding to the n^{th} sampling result, and
$${cos}_{1}^{e} ( n )$$
denotes a second theoretical result corresponding to the n^{th} sampling result; and
Vpp denotes a peak-to-peak value of the input signal, Fc denotes a carrier frequency of the input signal, N denotes a total number of the sampling results, n denotes the n^{th} sampling result, M denotes a number of the sub-sampling modules, and Fs denotes a total sampling rate; and
determining the sampling time offsets of the non-reference sub-sampling modules based on the sampling time offset of the reference sub-sampling module, the plurality of sampling results of each non-reference sub-sampling module, the first theoretical result corresponding to each sampling result, and the second theoretical result corresponding to each sampling result comprises:
calculating a sampling time offset
$${τ}_{m}^{e s t}$$
of a non-reference sub-sampling module having an m^{th} predetermined sampling time by a formula
$${τ}_{m}^{e s t} = \frac{arc tan ( \frac{{β}_{m}}{{α}_{m}} )}{2 π * F c} ,$$
where
$${α}_{m} = {\sum }_{n = 1}^{N} {sig\_s}_{m} ( n ) * {sin}_{m}^{e} ( n ) ;$$
$${β}_{m} = {\sum }_{n = 1}^{N} {sig\_s}_{m} ( n ) * {cos}_{m}^{e} ( n ) ;$$
$${sin}_{m}^{e} ( n ) = Vpp * sin ( 2 π * F c * ( \frac{m + M * ( n - 1 )}{F s} + {τ}_{1}^{e s t} ) ) ;$$
$${cos}_{m}^{e} ( n ) = Vpp * cos ( 2 π * F c * ( \frac{m + M * ( n - 1 )}{F s} + {τ}_{1}^{e s t} ) ) ;$$
and
sig_sₘ(n) denotes an n^{th} sampling result of the non-reference sub-sampling module,
$${sin}_{m}^{e} ( n )$$
denotes a first theoretical result corresponding to the n^{th} sampling result, and
$${cos}_{m}^{e} ( n )$$
denotes a second theoretical result corresponding to the n^{th} sampling result.

5. The method of claim 1, wherein after determining the sampling time offsets of the non-reference sub-sampling modules, the method further comprises:
determining a calibration scheme based on the sampling time offset of the reference sub-sampling module and the sampling time offsets of the non-reference sub-sampling modules, with the calibration scheme used for calibration of the sampling time offsets of the sub-sampling modules.

6. The method of claim 5, wherein determining the calibration scheme based on the sampling time offset of the reference sub-sampling module and the sampling time offsets of the non-reference sub-sampling modules comprises:
setting calibration factors for the sub-sampling modules based on the sampling time offsets of the sub-sampling modules, with the calibration factors used for calibration of the sampling results of the sub-sampling modules; or
adjusting the respective predetermined sampling time of each sub-sampling module based on the sampling time offsets of the sub-sampling modules.

7. The method of claim 5, wherein determining the calibration scheme based on the sampling time offset of the reference sub-sampling module and the sampling time offsets of the non-reference sub-sampling modules comprises:
determining that the reference sub-sampling module is not calibrated; and
determining a calibration scheme for the non-reference sub-sampling modules based on the sampling time offset of the reference sub-sampling module and the sampling time offsets of the non-reference sub-sampling modules.

8. A time-interleaved sampling device, comprising a processor, a storage device, and a plurality of sub-sampling modules;
the time-interleaved sampling device being configured to receive an input signal, and each sub-sampling module being configured to perform sampling at a respective predetermined sampling time;
the storage device storing a computer program executable by the processor, and the computer program, when executed by the processor, causing the processor to perform the following operations:
acquiring a plurality of sampling results of each sub-sampling module on the input signal, with each sampling result being a result obtained by performing sampling at one predetermined sampling time by the sub-sampling module;
determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and
determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling module than the reference sub-sampling module.

9. The time-interleaved sampling device of claim 8, wherein
the time-interleaved sampling device is a time interleaved analog-to-digital converter (ADC); and
the sub-sampling modules are sub-ADCs.

10. The time-interleaved sampling device of claim 8, wherein
a number of the sub-sampling modules is 2^{k}; and k is an integer greater than or equal to 2.

11. A non-transitory computer readable medium having stored thereon a computer program which, when executed by a processor, causes the processor to implement a method for calculating a sampling time offset applied to a time-interleaved sampling device comprising a plurality of sub-sampling modules, the time-interleaved sampling device being configured to receive an input signal, and each sub-sampling module being configured to sample the input signal at a respective predetermined sampling time; and the method comprising:
acquiring a plurality of sampling results of each sub-sampling module on the input signal, with each sampling result being a result obtained by performing sampling at one predetermined sampling time by each sub-sampling module:
determining a sampling time offset of a reference sub-sampling module based on the plurality of sampling results of the reference sub-sampling module, a first theoretical result corresponding to each sampling result, and a second theoretical result corresponding to each sampling result, with the reference sub-sampling module being one of the plurality of sub-sampling modules, the first theoretical result being a theoretical value of the input signal at a predetermined sampling time corresponding to each sampling result, the second theoretical result being a theoretical value of a derivative signal at a predetermined sampling time corresponding to each sampling result, and the derivative signal being a derivative of the input signal; and
determining sampling time offsets of non-reference sub-sampling modules based on the sampling time offset of the reference sub-sampling module, the plurality of sampling results of each non-reference sub-sampling module, a first theoretical result corresponding to each sampling result, and a second theoretical result corresponding to each sampling result, with the non-reference sub-sampling modules being other sub-sampling modules than the reference sub-sampling module.

12. The time-interleaved sampling device of claim 8, wherein
the input signal is a sinusoidal signal.

13. The time-interleaved sampling device of claim 8, wherein
the reference sub-sampling module is a sub-sampling module having an earliest predetermined sampling time.

14. The time-interleaved sampling device of claim 8, wherein the input signal is a sinusoidal signal, and the reference sub-sampling module is a sub-sampling module having an earliest predetermined sampling time;
determining the sampling time offset of the reference sub-sampling module based on the plurality of sampling results of the reference sub-sampling module, the first theoretical result corresponding to each sampling result, and the second theoretical result corresponding to each sampling result comprises:
calculating the sampling time offset
$${τ}_{1}^{e s t}$$
of the reference sub-sampling module by a formula
$${τ}_{1}^{e s t} = \frac{arc tan ( \frac{{β}_{1}}{{α}_{1}} )}{2 π * F c} ,$$
where
$${α}_{1} = {\sum }_{n = 1}^{N} {sig\_s}_{1} ( n ) * {sin}_{1}^{e} ( n ) ;$$
$${β}_{1} = {\sum }_{n = 1}^{N} {sig\_s}_{1} ( n ) * {cos}_{1}^{e} ( n ) ;$$
$${sin}_{1}^{e} ( n ) = Vpp * sin ( 2 π * F c * ( \frac{1 + M * ( n - 1 )}{F s} ) ) ;$$
$${cos}_{1}^{e} ( n ) = Vpp * cos ( 2 π * F c * ( \frac{1 + M * ( n - 1 )}{F s} ) ) ;$$
sig_s₁(n) denotes an n^{th} sampling result of the reference sub-sampling module,
$${sin}_{1}^{e} ( n )$$
denotes a first theoretical result corresponding to the n^{th} sampling result, and
$${cos}_{1}^{e} ( n )$$
denotes a second theoretical result corresponding to the n^{th} sampling result; and
Vpp denotes a peak-to-peak value of the input signal, Fc denotes a carrier frequency of the input signal, N denotes a total number of the sampling results, n denotes the n^{th} sampling result, M denotes a number of the sub-sampling modules, and Fs denotes a total sampling rate; and
determining the sampling time offsets of the non-reference sub-sampling modules based on the sampling time offset of the reference sub-sampling module, the plurality of sampling results of each non-reference sub-sampling module, the first theoretical result corresponding to each sampling result, and the second theoretical result corresponding to each sampling result comprises:
calculating a sampling time offset
$${τ}_{m}^{est}$$
of a non-reference sub-sampling module having an m^{th} predetermined sampling time by a formula
$${τ}_{m}^{est} = \frac{arctan ( \frac{{β}_{m}}{{α}_{m}} )}{2 π * Fc} ,$$
where
$${α}_{m} {\sum }_{n = 1}^{N} {sig\_s}_{m} ( n ) * {sin}_{m}^{e} ( n ) ;$$
$${β}_{m} {\sum }_{n = 1}^{N} {sig\_s}_{m} ( n ) * {cos}_{m}^{e} ( n ) ;$$
$${sin}_{m}^{e} ( n ) = Vpp * sin ( 2 π * Fc * ( \frac{m + M * ( n - 1 )}{Fs} + {τ}_{1}^{est} ) ) ;$$
$${cos}_{m}^{e} ( n ) = Vpp * cos ( 2 π * Fc * ( \frac{m + M * ( n - 1 )}{Fs} + {τ}_{1}^{est} ) ) ;$$
and
sig_sₘ(n) denotes an n^{th} sampling result of the non-reference sub-sampling module,
$${sin}_{m}^{e} ( n )$$
denotes a first theoretical result corresponding to the n^{th} sampling result, and
$${cos}_{m}^{e} ( n )$$
denotes a second theoretical result corresponding to the n^{th} sampling result.

15. The time-interleaved sampling device of claim 8, wherein the computer program, when executed by the processor, further causes the processor to:
after determining the sampling time offsets of the non-reference sub-sampling modules,
determine a calibration scheme based on the sampling time offset of the reference sub-sampling module and the sampling time offsets of the non-reference sub-sampling modules, with the calibration scheme used for calibration of the sampling time offsets of the sub-sampling modules.

16. The time-interleaved sampling device of claim 15, wherein determining the calibration scheme based on the sampling time offset of the reference sub-sampling module and the sampling time offsets of the non-reference sub-sampling modules comprises:
setting calibration factors for the sub-sampling modules based on the sampling time offsets of the sub-sampling modules, with the calibration factors used for calibration of the sampling results of the sub-sampling modules; or
adjusting the respective predetermined sampling time of each sub-sampling module based on the sampling time offsets of the sub-sampling modules.

17. The time-interleaved sampling device of claim 15, wherein determining the calibration scheme based on the sampling time offset of the reference sub-sampling module and the sampling time offsets of the non-reference sub-sampling modules comprises:
determining that the reference sub-sampling module is not calibrated; and
determining a calibration scheme for the non-reference sub-sampling modules based on the sampling time offset of the reference sub-sampling module and the sampling time offsets of the non-reference sub-sampling modules.

18. The non-transitory computer readable medium of claim 11, wherein
the input signal is a sinusoidal signal.

19. The non-transitory computer readable medium of claim 11, wherein
the reference sub-sampling module is a sub-sampling module having an earliest predetermined sampling time.

20. The non-transitory computer readable medium of claim 11, wherein the input signal is a sinusoidal signal, and the reference sub-sampling module is a sub-sampling module having an earliest predetermined sampling time;
determining the sampling time offset of the reference sub-sampling module based on the plurality of sampling results of the reference sub-sampling module, the first theoretical result corresponding to each sampling result, and the second theoretical result corresponding to each sampling result comprises:
calculating the sampling time offset
$${τ}_{1}^{est}$$
of the reference sub-sampling module by a formula
$${τ}_{1}^{est} = \frac{arctan ( \frac{{β}_{1}}{{α}_{1}} )}{2 π * Fc} ,$$
where
$${α}_{1} {\sum }_{n = 1}^{N} {sig\_s}_{1} ( n ) * {sin}_{1}^{e} ( n ) ;$$
$${β}_{1} {\sum }_{n = 1}^{N} {sig\_s}_{1} ( n ) * {cos}_{1}^{e} ( n ) ;$$
$${sin}_{1}^{e} ( n ) = Vpp * sin ( 2 π * Fc * ( \frac{1 + M * ( n - 1 )}{Fs} ) ) ;$$
$${cos}_{1}^{e} ( n ) = Vpp * cos ( 2 π * Fc * ( \frac{1 + M * ( n - 1 )}{Fs} ) ) ;$$
sig_s₁(n) denotes an n^{th} sampling result of the reference sub-sampling module,
$${sin}_{1}^{e}$$
denotes a first theoretical result corresponding to the n^{th} sampling result, and
$${cos}_{1}^{e}$$
denotes a second theoretical result corresponding to the n^{th} sampling result; and
Vpp denotes a peak-to-peak value of the input signal, Fc denotes a carrier frequency of the input signal, N denotes a total number of the sampling results, n denotes the n^{th} sampling result, M denotes a number of the sub-sampling modules, and Fs denotes a total sampling rate; and
determining the sampling time offsets of the non-reference sub-sampling modules based on the sampling time offset of the reference sub-sampling module, the plurality of sampling results of each non-reference sub-sampling module, the first theoretical result corresponding to each sampling result, and the second theoretical result corresponding to each sampling result comprises:
calculating a sampling time offset
$${τ}_{m}^{est}$$
of a non-reference sub-sampling module having an m^{th} predetermined sampling time by a formula
$${τ}_{m}^{est} = \frac{arctan ( \frac{{β}_{m}}{{α}_{m}} )}{2 π * Fc} ,$$
where
$${α}_{m} {\sum }_{n = 1}^{N} {sig\_s}_{m} ( n ) * {sin}_{m}^{e} ( n ) ;$$
$${β}_{m} {\sum }_{n = 1}^{N} {sig\_s}_{m} ( n ) * {cos}_{m}^{e} ( n ) ;$$
$${sin}_{m}^{e} ( n ) = Vpp * sin ( 2 π * Fc * ( \frac{m + M * ( n - 1 )}{Fs} + {τ}_{1}^{est} ) ) ;$$
$${cos}_{m}^{e} ( n ) = Vpp * cos ( 2 π * Fc * ( \frac{m + M * ( n - 1 )}{Fs} + {τ}_{1}^{est} ) ) ;$$
sig_sₘ(n) denotes an n^{th} sampling result of the non-reference sub-sampling module,
$${sin}_{m}^{e} ( n )$$
denotes a first theoretical result corresponding to the n^{th} sampling result, and
$${cos}_{m}^{e} ( n )$$
denotes a second theoretical result corresponding to the n^{th} sampling result.
